(19) United States
(12) Patent Application Publication
(10) Pub. No.: US 2026/0344004 A1
(43) Pub. Date: Oct. 29, 2026

(54) METHOD OF MANUFACTURING A SEMICONDUCTOR DEVICE HAVING AN ELEVATED SOURCE/DRAIN REGION

(71) Applicant: SK hynix Inc., Gyeonggi-do (KR)

(72) Inventor: Young Gwang YOON, Gyeonggi-do (KR)

(21) Appl. No.: 19/375,212

(22) Filed: Oct. 31, 2025

(30) Foreign Application Priority Data
Apr. 29, 2025 (KR) 10-2025-0056152

(51) Int. Cl. H10D 84/01; H10D 30/01; H10D 62/13; H10D 62/832; H10D 64/23; H10D 64/66; H10D 84/83

(52) U.S. Cl. CPC H10D 84/0128; H10D 30/027; H10D 62/151; H10D 62/832; H10D 64/669; H10D 84/013; H10D 84/0135; H10D 84/0144; H10D 84/0147; H10D 64/256; H10D 84/83125

(57) ABSTRACT

A method of manufacturing a semiconductor device is provided. The method includes forming an isolation region defining an active region over a substrate; forming a preliminary channel layer over the active region; forming a gate stack over the preliminary channel layer; forming a spacer layer over a side surface and an upper surface of the gate stack, wherein the spacer layer is formed to leave an exposed portion of the preliminary channel layer; forming a channel layer by removing the exposed portion of the preliminary channel layer, wherein the channel layer is formed to leave an exposed portion of the active region, and forming an elevated source and drain region over the exposed portion of the active region.

### CROSS-REFERENCE TO RELATED APPLICATIONS

This patent document claims priority under 35 U.S.C. 119(a) to Korean Patent Application No. 10-2025-0056152, filed on Apr. 29, 2025, which is incorporated herein by reference in its entirety.

### TECHNICAL FIELD

Embodiments of the present disclosure relate to a semiconductor device having an elevated source/drain region and a method of manufacturing the semiconductor device.

### BACKGROUND

Semiconductor devices have emerged as key components in the electronics industry based on characteristics of the semiconductor devices such as miniaturization, multifunctionality, and/or low manufacturing cost. To improve driving properties of transistors of semiconductor devices, semiconductor devices including a transistor structure having an elevated source and drain (source/drain) region have been proposed.

### SUMMARY

An embodiment of the present disclosure provides a transistor structure having an elevated source/drain region.

An embodiment of the present disclosure provides a semiconductor device having the transistor structure.

Embodiments of the present disclosure provide a method of forming the transistor structure and a method of manufacturing the semiconductor device.

In accordance with an embodiment of the present disclosure, a method of manufacturing a semiconductor device may include forming an isolation region defining an active region over a substrate; forming a preliminary channel layer over the active region; forming a gate stack over the preliminary channel layer; forming a spacer layer over a side surface and an upper surface of the gate stack, wherein the spacer layer is formed to leave an exposed portion of the preliminary channel layer; forming a channel layer by removing the exposed portion of the preliminary channel layer, wherein the channel layer is formed to leave an exposed portion of the active region, and forming an elevated source and drain (source/drain) region over the exposed portion of the active region.

In accordance with an embodiment of the present disclosure, a method of manufacturing a semiconductor device includes forming a crystalline silicon germanium layer over an active region; forming a gate stack over the crystalline silicon germanium layer; forming a spacer layer over a side surface and an upper surface of the gate stack to leave an exposed portion of the crystalline silicon germanium layer; removing the exposed portion of the crystalline silicon germanium layer to leave an exposed portion of the active region; and forming an elevated source and drain (source/drain) region over the exposed portion of the active region. The exposed portion of the crystalline silicon germanium layer has a first lateral width. The exposed portion of the active region has a second lateral width. The second lateral width is greater than the first lateral width.

In accordance with an embodiment of the present disclosure, a method of manufacturing a semiconductor device includes forming a crystalline silicon germanium layer over an active region; forming a gate stack over the crystalline silicon germanium layer; forming a spacer layer over a side surface and an upper surface of the gate stack to leave an exposed portion of the crystalline silicon germanium layer; removing a portion of the crystalline silicon germanium layer to leave an exposed portion of the active region; and forming an elevated source and drain (source/drain) region over the exposed portion of the active region. The elevated source/drain region includes a top portion having a side surface in contact with the spacer layer, the top portion having a first lateral width; and a bottom portion having a side surface in contact with the crystalline silicon germanium layer, the bottom portion having a second lateral width. The second lateral width is greater than the first lateral width.

In accordance with an embodiment of the present disclosure, a semiconductor device includes an isolation region, defining an active region, disposed in a substrate; a channel layer disposed over the active region; a gate stack disposed over the channel layer; a spacer layer disposed over a side surface and an upper surface of the gate stack; and an elevated source and drain (source/drain) region disposed over the active region. The elevated source/drain region includes a top portion having a side surface in contact with the spacer layer and a bottom portion having a side surface in contact with the channel layer. The top portion has a first lateral width. The bottom portion has a second lateral width. The second lateral width is greater than the first lateral width.

In accordance with an embodiment of the present disclosure, a semiconductor device includes a silicon germanium layer over an active region; a gate stack over the silicon germanium layer; a spacer layer over a side surface and an upper surface of the gate stack; and an elevated source and drain (source/drain) region over the active region. The elevated source/drain region includes a top portion having a side surface in contact with the spacer layer and a bottom portion having a side surface in contact with the silicon germanium layer. The top portion has a first lateral width. The bottom portion has a second lateral width. The second lateral width is greater than the first lateral width.

In accordance with an embodiment of the present disclosure, a semiconductor device includes an active region including a single crystalline silicon layer; a silicon germanium layer disposed over the active region; a gate stack disposed over the silicon germanium layer; a spacer layer disposed over a side surface and an upper surface of the gate stack to leave an exposed portion of the silicon germanium layer; an elevated source and drain (source/drain) region disposed over the exposed portion of the active region; an insulating liner layer conformally disposed over the spacer layer and the elevated source/drain region; an interlayer insulating layer disposed over the insulating liner layer; and a contact plug, connected to the elevated source/drain region, vertically passing through the interlayer insulating layer and the insulating liner layer. The elevated source/drain region includes a top portion having a side surface in contact with the spacer layer and a bottom portion having a side surface in contact with the channel layer. The top portion has a first lateral width. The bottom portion has a second lateral width. The second lateral width is greater than the first lateral width.

These and other features and advantages of the embodiments of the present disclosure will become apparent to those skilled in the art from the following detailed description in conjunction with the following drawings.

### BRIEF DESCRIPTION OF THE DRAWINGS

FIG. 1 is a schematic layout illustrating a semiconductor device according to an embodiment of the present disclosure.

FIGS. 2 to 14 are longitudinal cross-sectional views taken along the line I-I′ of FIG. 1 to illustrate a method of manufacturing a semiconductor device according to an embodiment of the present disclosure.

### DETAILED DESCRIPTION

Embodiments of the present disclosure are described in detail with reference to the accompanying drawings. Specific structural or functional descriptions of specific embodiments are provided as examples to describe the technical concepts that are disclosed in the present application. However, it should be understood that various other examples or embodiments in accordance with the technical concepts of the present disclosure may be carried out in various forms by those with ordinary skill in the art without departing from the scope of the present disclosure. Hence, the present invention is not limited only to the described examples or embodiments.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,”“beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described hereunder. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the descriptions below. All changes within the meaning and range of equivalency of the claims are included within their scope.

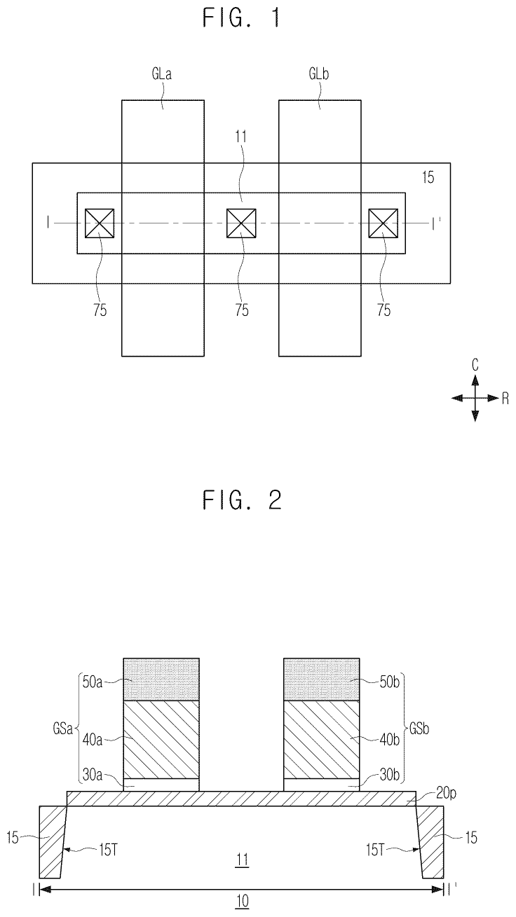

FIG. 1 is a schematic layout illustrating a semiconductor device according to an embodiment of the present disclosure. Referring to FIG. 1, the semiconductor device may include an isolation region 15, an active region 11, a first gate line GLa and a second gate line GLb, and contact plugs 75. The isolation region 15 may define the active region 11. The first gate line GLa and the second gate line GLb may cross the active region 11 in parallel with each other. The contact plugs 75 may be disposed on the active region 11 to be adjacent to side surfaces of the first and second gate lines GLa and GLb. In an embodiment, the active region 11 may further extend in a row direction R. In an embodiment, the first and second gate lines GLa and GLb may further extend in a column direction C. The row direction and the column direction may be perpendicular to each other.

FIGS. 2 to 14 are longitudinal cross-sectional views taken along the line I-I′ of FIG. 1 to illustrate a method of manufacturing a semiconductor device according to an embodiment of the present disclosure. Referring to FIG. 2, the method may include forming isolation regions 15 defining an active region 11 in a substrate 10, forming a preliminary channel layer 20p on a surface of the active region 11, and forming gate stacks GSa and GSb on the preliminary channel layer 20p.

The substrate 10 may include a single crystalline silicon layer. For example, the substrate 10 may include a single crystalline silicon wafer or a silicon-on-insulator (SOI) substrate.

Forming the isolation regions 15 may include forming isolation trenches 15T in the substrate 10, forming an isolation liner layer such as a silicon oxide layer on inner walls of the isolation trenches 15T, and forming a filling insulating material such as a silicon nitride layer on the isolation liner layer to fill the isolation trenches 15T.

The active region 11 defined by the isolation regions 15 may be used as a channel region, a source region, and a drain region of the transistor. The active region 11 may be a region doped with N-type ions such as phosphorus (P) or arsenic (As). A surface of the active region 11 may be an {100} plane in the Miller Index.

Forming the preliminary channel layer 20p may include performing an epitaxial growth process to form a crystalline silicon germanium layer (c-SiGe) on the active region 11. The preliminary channel layer 20p may be only formed on the surface of the active region 11 and may not be formed on the isolation region 15.

Forming the gate stacks GSa and GSb may include forming a first gate stack GSa and a second gate stack GSb disposed on the preliminary channel layer 20p, adjacent to each other. The first gate stack GSa and the second gate stack GSb may correspond to the first gate line GLa and the second gate line GLb of FIG. 1, respectively. Forming the first and second gate stacks GSa and GSb may include forming a first material layer for gate dielectric layers 30a and 30b on the preliminary channel layer 20p, forming a second material layer for gate electrode layers 40a and 40b on the first material layer, forming a third material layer for gate capping layers 50a and 50b on the second material layer, and patterning the first to third material layers by performing a patterning process including a photolithography process and an etching process.

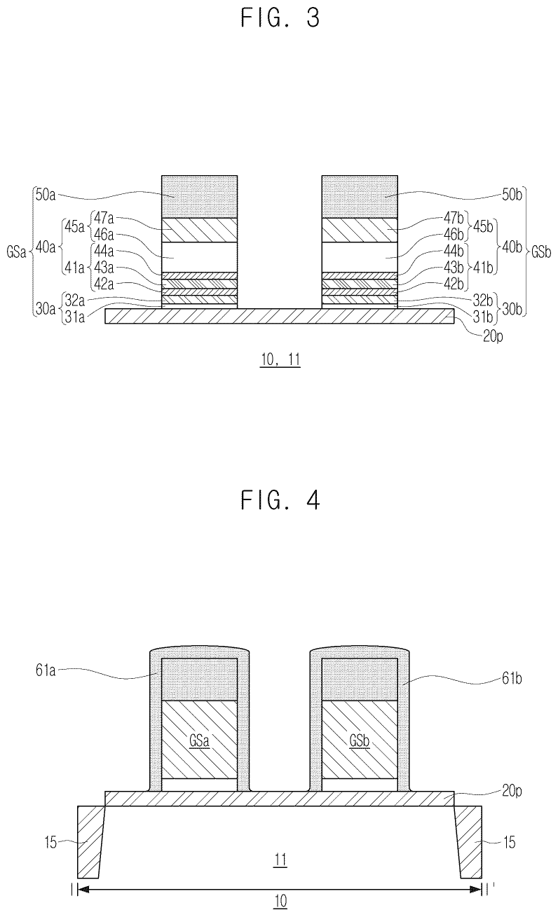

FIG. 3 is a diagram illustrating the gate stacks GSa and GSb of FIG. 2 in detail. Referring to FIG. 3, the gate dielectric layer 30a may include an interfacial insulating layer 31a, and a high-k dielectric layer 32a on the interfacial insulating layer 31a. The gate dielectric layer 30b may include an interfacial insulating layer 31b, and a high-k dielectric layer 32b on the interfacial insulating layer 31b. The interfacial insulating layers 31a and 31b may be directly formed on the preliminary channel layer 20p. Each of the interfacial insulating layers 31a and 31b may include one of a silicon oxide layer or a silicon germanium oxide layer formed by performing an oxidation process or a deposition process. Each of the high-k dielectric layers 32a and 32b may include at least one of a hafnium oxide layer, a molybdenum oxide layer, a zirconium oxide layer, or other metal oxide layers formed by performing a deposition process.

The gate electrode layer 40a may include a lower gate electrode layers 41a and an upper gate dielectric layer 45a. The gate electrode layer 40b may include a lower gate electrode layer 41b and an upper gate dielectric layer 45b. The lower gate electrode layers 41a and 41b may include first lower gate electrode layers 42a and 42b, second lower gate electrode layers 43a and 43b, and third lower gate electrode layers 44a and 44b, respectively. The upper gate dielectric layers 45a and 45b may include first upper gate dielectric layers 46a and 46b and second upper gate dielectric layers 47a and 47b, respectively.

Each of the first lower gate electrode layers 42a and 42b may include a barrier layer or a work function control layer. Each of the first lower gate electrode layers 42a and 42b may include a metal nitride layer. For example, each of the first lower gate electrode layers 42a and 42b may include at least one of a titanium nitride layer, a tantalum nitride layer, a tungsten nitride layer, and an aluminum nitride layer.

Each of the second lower gate electrode layers 43a and 43b may include a work function control layer. For example, each of the second lower gate electrode layers 43a and 43b may include a metal layer such as an aluminum layer. In an embodiment, the second lower gate electrode layers 43a and 43b may include a dipole material layer. For example, each of the second lower gate electrode layers 43a and 43b may include at least one of a lanthanum layer, a lanthanum oxide layer, an aluminum layer, a lanthanum aluminum layer, or a lanthanum aluminum oxide layer. In another embodiment, the second lower gate electrode layers 43a and 43b may be omitted.

Each of the third lower gate electrode layers 44a and 44b may include a barrier layer. Each of the third lower gate electrode layers 44a and 44b may include a metal nitride layer. For example, each of the third lower gate electrode layers 44a and 44b may include at least one of a titanium nitride layer, a tantalum nitride layer, a tungsten nitride layer, and an aluminum nitride layer. In an embodiment, each of the third lower gate electrode layers 44a and 44b may include a metal silicide layer. In an embodiment, at least one of the first lower gate electrode layers 42a and 42b or the third lower gate electrode layers 44a and 4b may be omitted.

Each of the first upper gate electrode layers 46a and 46b may include a polycrystalline silicon layer. Each of the second upper gate electrode layers 47a and 47b may include a metal layer. In an embodiment, the upper gate electrode layers 45a and 45b may further include a metal silicide layer disposed between the first upper gate electrode layers 46a and 46b and the second upper gate electrode layers 47a and 47b, respectively.

Referring to FIG. 4, the method may further include conformally forming inner spacer layers 61a and 61b on both side surfaces and an upper surface of each of the gate stacks GSa and GSb, respectively. The inner spacer layers 61a and 61b may expose a portion of the preliminary channel layer 20p. Lower ends of the inner spacer layers 61a and 61b may be in contact with the preliminary channel layer 20p. Lower ends of the inner spacer layers 61a and 61b may have a footing shape or a hem shape. Forming the inner spacer layers 61a and 61b may include forming an insulating layer based on silicon nitride by performing a first spacer deposition process, and patterning the insulating layer to partially expose a surface of the preliminary channel layer 20p by performing a first spacer etch-back process. The method may further include forming low-concentration ion implant layers (not shown) in the preliminary channel layer 20p by performing a lightly doped drain (LDD) implant process using the inner spacer layers 61a and 61b as an ion implant mask. The LDD implant process may include implanting P-type ions such as boron (B).

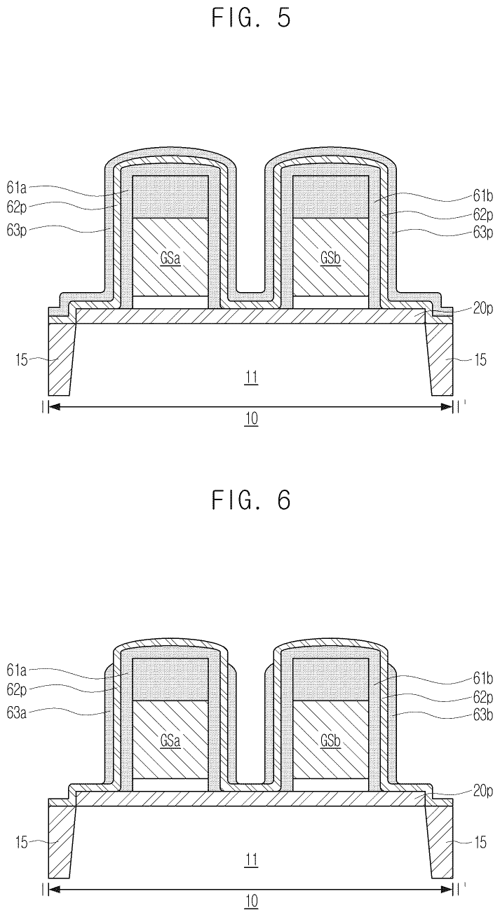

Referring to FIG. 5, the method may further include conformally forming a preliminary intermediate spacer layer 62p on the inner spacer layers 61a and 61b and exposed portions of the preliminary channel layer 20p, and conformally forming a preliminary outer spacer layer 63p on the preliminary intermediate spacer layer 62p. Forming the preliminary intermediate spacer layer 62p may include performing a second spacer deposition process to conformally form an insulating layer based on silicon oxide on the side surfaces and the upper surfaces of the inner spacer layers 61a and 61b, exposed portions of the preliminary channel layer 20p, and isolation regions 15. Forming the preliminary outer spacer layer 63p may include performing a third spacer deposition process to conformally form an insulating layer based on silicon nitride on a surface of the preliminary intermediate spacer layer 62p.

Referring to FIG. 6, the method may further include performing a second spacer etch-back process to etch-back the preliminary outer spacer layer 63p to form outer spacer layers 63a and 63b. Portions of the preliminary outer spacer layer 63p on an upper portion of the gate stacks GSa and GSb and portions of the preliminary outer spacer layer 63p on the exposed portions of the preliminary channel layer 20p may be removed. Portions of the preliminary intermediate spacer layer 62p on the upper portions of the gate stacks GSa and GSb and the exposed portions of the preliminary channel layer 20p may be exposed.

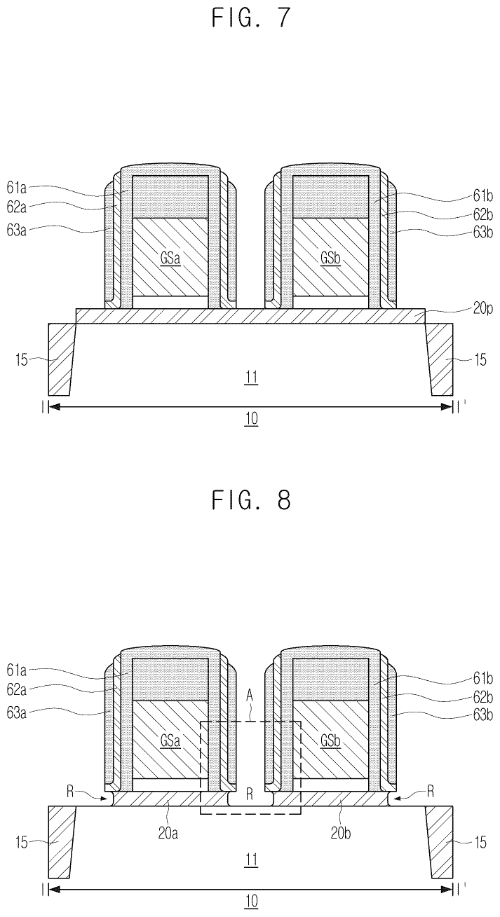

Referring to FIG. 7, the method may further include performing a third spacer etch-back process to etch-back the preliminary intermediate spacer layer 62p to form intermediate spacer layers 62a and 62b. The exposed portions of the preliminary channel layer 20p may be removed. A portion of the preliminary intermediate spacer layer 62p on the upper portions of the gate stacks GSa and GSb and a portion of the preliminary intermediate spacer layer 62p on the exposed portions of the preliminary channel layer 20p may be removed. Portions of inner spacer layers 61a and 61b on the upper portions of the gate stacks GSa and GSb and the preliminary channel layer 20p may be exposed.

Referring to FIG. 8, the method may further include forming channel layers 20a and 20b by partially removing the exposed preliminary channel layer 20p. The channel layers 20a and 20b may have recessed portions R in a lateral direction (shown within the broken lines of area A). Recessing the exposed portion of the preliminary channel layer 20p may include performing an isotropic etching process. The isotropic etching process may include a wet etching process or a radial dry etching process. Each of the recess portions R of the channel layers 20a and 20b may have an undercut shape. The intermediate spacer layers 62a and 62b and the outer spacer layers 63a and 63b may protrude in an overhang shape on the recess portions R. Portions of the active region 11 may be exposed by the recess portions R.

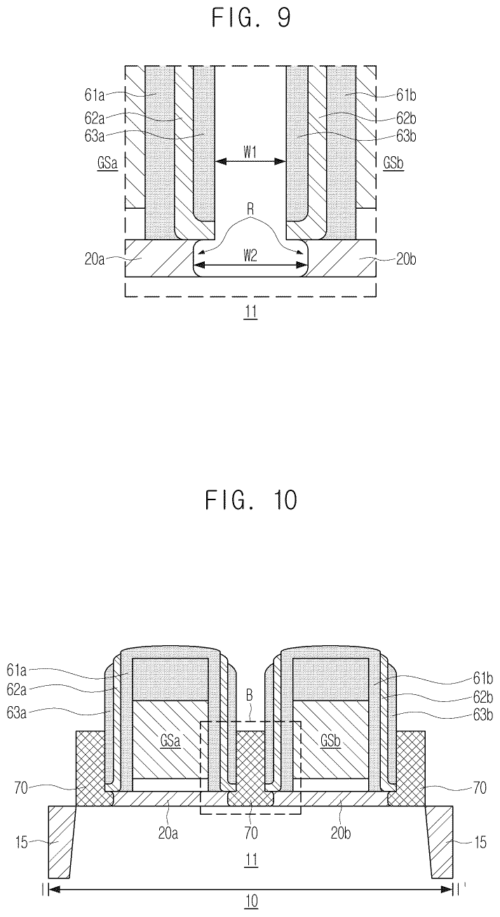

FIG. 9 is an enlarged view of the area A of FIG. 8. Referring to FIG. 9, a space between the outer spacer layers 63a and 63b may have a first lateral width W1 in the lateral direction, and the recess portion R between the channel layers 20a and 20b may have a second lateral width W2 in the lateral direction. The second width W2 may be greater than the first width W1.

Referring to FIG. 10, the method may further include performing an epitaxial growth process to form elevated source/drain regions 70 on the exposed portion of the active region 11. The elevated source/drain regions 70 may include a single crystalline silicon layer. The exposed surface of the active region 11 may be flat without inclination, and may have the {100} plane in the Miller index. Thus, the elevated source/drain regions 70 can grow to have a flat upper surface in a vertical direction.

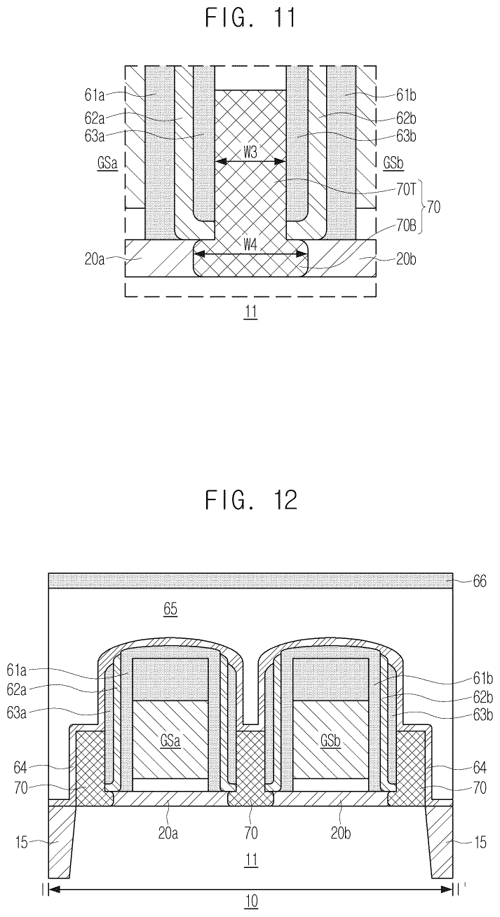

FIG. 11 is an enlarged view of the area B of FIG. 10. Referring to FIG. 11, each of the elevated source/drain regions 70 may have a top portion 70T between the outer spacer layers 63a and 63b and a bottom portion 70B between the channel layers 20a and 20b. The top portion 70T of the elevated source/drain regions 70 may have a third lateral width W3 in the lateral direction. The bottom portion 70B of the elevated source/drain regions 70 may have a fourth lateral width W4 in the lateral direction. The top portion 70T of the elevated source/drain regions 70 may be in contact with side surfaces of the outer spacer layers 63a and 63b. The bottom portion 70B of the elevated source/drain regions 70 may be in contact with side surfaces of the channel layers 20a and 20b. The fourth lateral width W4 may be greater than the third lateral width W3.

Referring to FIG. 12, the method may further include forming a liner layer 64, an interlayer insulating layer 65, and a capping insulating layer 66. Forming the liner layer 64 may include conformally forming an insulating layer based on silicon nitride by performing a deposition process. For example, the liner layer 64 may be formed on exposed surfaces of the outer spacer layers 63a and 63b, exposed surfaces of the intermediate spacer layers 62a and 62b, exposed surfaces of the inner spacer layers 61a and 61b, exposed surfaces of the elevated source/drain regions 70, and exposed surfaces of the isolation regions 15. Forming the interlayer insulating layer 65 may include forming an insulating layer based on silicon nitride by performing a deposition process. The interlayer insulating layer 65 may be formed to be thicker than the liner layer 64 to cover the liner layer 64. In an embodiment, the method may further include planarizing an upper surface of the interlayer insulating layer 65 by performing a chemical mechanical polishing (CMP) process. Forming the capping insulating layer 66 may include forming an insulating layer based on silicon nitride by performing a deposition process. The capping insulating layer 66 may have etch selectivity with respect to the interlayer insulating layer 65.

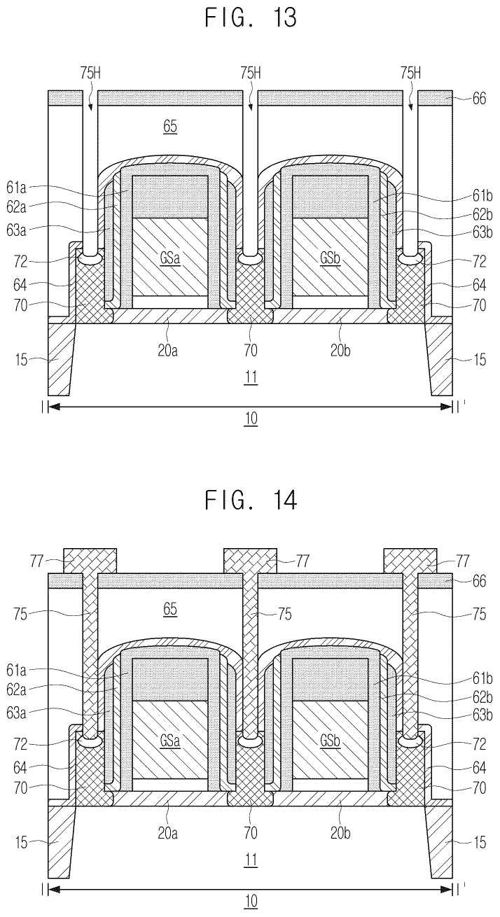

Referring to FIG. 13, the method may further include forming contact holes 75H. The contact holes 75H may vertically penetrate the capping insulating layer 66, the interlayer insulating layer 65, and the liner layer 64 to expose the elevated source/drain regions 70. The contact holes 75H may extend into the elevated source/drain regions 70. Upper surfaces of the elevated source/drain regions 70 may be recessed. The method may further include forming ion implantation regions 72 in upper portions of the elevated source/drain regions 70 by implanting ions through the contact holes 75H. The ion implantation regions 72 can reduce contact resistance. The ion implantation regions 72 may include P-type ions such as boron (B).

Referring to FIG. 14, the method may further include filling the contact holes 75H with a conductive material to form contact plugs 75 and forming pad patterns 77 on the contact plugs 75. Forming the contact plugs 75 may include conformally forming contact barrier layers (not shown) on inner walls and bottom surfaces of the contact holes 75H, and filling the contact holes 75H with conductive materials (for example, one or more types of conductive materials) on the contact barrier layers. Each of the contact plugs 75 may have a pillar shape. In a top view, each of the pad patterns 77 may have a circular shape or a polygonal shape. In an embodiment, each of the pad patterns 77 may be line patterns extending in a horizontal direction.

In accordance with the embodiments of the present disclosure, the elevated source/drain regions can only grow in a vertical direction, and the adjacent elevated source/drain regions cannot be in contact with or connected with each other.

In accordance with the embodiments of the present disclosure, the elevated source/drain region can have a top portion having a first lateral width and a bottom portion having a second lateral width. The second lateral width can be greater than the first lateral width. Accordingly, the elevated source/drain region having the top portion and the bottom portion can have a lower source/drain resistance than that of an elevated source/drain region having a top portion and a bottom portion with the same lateral width.

While the present invention has been described with respect to specific embodiments, it will be apparent to those skilled in the art that various changes and modifications may be made without departing from the technical concepts and scope of the disclosure as defined in the following claims. Furthermore, the embodiments may be combined to form additional embodiments.

What is claimed is:

1. A method of manufacturing a semiconductor device comprising:
forming an isolation region defining an active region over a substrate;
forming a preliminary channel layer over the active region;
forming a gate stack over the preliminary channel layer;
forming a spacer layer over a side surface and an upper surface of the gate stack, wherein the spacer layer is formed to leave an exposed portion of the preliminary channel layer;
forming a channel layer by removing the exposed portion of the preliminary channel layer, wherein the channel layer is formed to leave an exposed portion of the active region; and
forming an elevated source and drain (source/drain) region over the exposed portion of the active region.

2. The method of claim 1, wherein forming the preliminary channel layer includes:
performing an epitaxial growth process to form a crystalline silicon germanium layer over the active region.

3. The method of claim 1, wherein forming the gate stack includes:
forming, over the preliminary channel layer, a gate dielectric layer including a high-k dielectric material layer;
forming, over the gate dielectric layer, a lower gate electrode layer including a first metal nitride layer;
forming, over the lower gate electrode layer, an upper gate electrode layer including a metal layer; and
forming an insulating gate capping layer over the upper gate electrode layer.

4. The method of claim 3, wherein forming the gate dielectric layer includes:
forming, over the preliminary channel layer, an interfacial insulating layer based on silicon oxide; and
forming a high-k dielectric layer over the interfacial insulating layer.

5. The method of claim 3, wherein forming the lower gate electrode layer includes:
forming a first metal nitride layer over the gate dielectric layer;
forming a work function control layer over the first metal nitride layer; and
forming a second metal nitride layer over the work function control layer.

6. The method of claim 3, wherein forming the upper gate electrode layer includes:
forming a polycrystalline silicon layer over the lower gate electrode layer, and
wherein the metal layer is formed over the polycrystalline silicon layer.

7. The method of claim 1, wherein forming the spacer layer includes:
conformally forming an inner spacer layer over the side surface and the upper surface of the gate stack;
conformally forming an intermediate spacer layer over a side surface of the inner spacer layer; and
conformally forming an outer spacer layer over a side surface of the intermediate spacer layer.

8. The method of claim 7, wherein forming the inner spacer layer includes:
forming a preliminary inner spacer layer over the side surface and the upper surface of the gate stack, and the exposed portion of the preliminary channel layer by performing a first spacer deposition process; and
removing the preliminary inner spacer layer over the exposed portion of the preliminary channel layer by performing a first spacer etch process.

9. The method of claim 8, wherein forming the intermediate spacer layer includes:
conformally forming a preliminary intermediate spacer layer over a side surface and an upper surface of the inner spacer layer and the exposed portion of the preliminary channel layer by performing a second spacer deposition process; and
removing the preliminary intermediate spacer layer over the upper surface of the inner spacer layer and the exposed portion of the preliminary channel layer by performing a second spacer etch process.

10. The method of claim 9, wherein forming the outer spacer layer includes:
forming a preliminary outer spacer layer over a side surface and an upper surface of the preliminary intermediate spacer layer by performing a third spacer deposition process; and
removing the preliminary outer spacer layer over the upper surface of the preliminary intermediate spacer layer and the exposed portion of the preliminary channel layer by performing a third spacer etch process.

11. The method of claim 1, further comprising:
conformally forming a liner layer over a surface of the spacer layer;
forming an interlayer insulating layer over the liner layer; and
forming a capping insulating layer over the interlayer insulating layer.

12. The method of claim 11, wherein conformally forming the liner layer includes conformally forming the liner layer over a surface of the elevated source and drain (source/drain) region.

13. The method of claim 11, further comprising:
forming a contact hole vertically penetrating the capping insulating layer and the interlayer insulating layer to expose the elevated source/drain region;
forming an ion implantation region by implanting ions into the exposed source/drain region in the contact hole; and
forming a contact plug by filling the contact hole with conductive materials.

14. The method of claim 1,
wherein forming the channel layer by removing the exposed portion of the preliminary channel layer includes recessing the preliminary channel layer in a lateral direction by performing an isotropic etching process.

15. The method of claim 14, wherein:
the exposed portion of the preliminary channel layer has a first lateral width,
a surface of the exposed portion of the active region has a second lateral width, and
the second lateral width is greater than the first lateral width.

16. The method of claim 15, wherein:
the elevated source/drain region includes a top portion having a third lateral width and a bottom portion having a fourth lateral width, and
the fourth lateral width is greater than the third lateral width.

17. The method of claim 16, wherein:
a side surface of the top portion is in contact with the outer spacer layer, and
a side surface of the bottom portion is in contact with the channel layer.

18. A method of manufacturing a semiconductor device comprising:
forming a crystalline silicon germanium layer over an active region;
forming a gate stack over the crystalline silicon germanium layer;
forming a spacer layer over a side surface and an upper surface of the gate stack to leave an exposed portion of the crystalline silicon germanium layer;
removing the exposed portion of the crystalline silicon germanium layer to leave an exposed portion of the active region; and
forming an elevated source and drain (source/drain) region over the exposed portion of the active region,
wherein:
the exposed portion of the crystalline silicon germanium layer has a first lateral width,
the exposed portion of the active region has a second lateral width, and
the second lateral width is greater than the first lateral width.

19. The method of claim 18,
wherein removing the exposed portion of the crystalline silicon germanium layer includes recessing the crystalline silicon germanium layer in a lateral direction.

20. A method of manufacturing a semiconductor device comprising:
forming a crystalline silicon germanium layer over an active region;
forming a gate stack over the crystalline silicon germanium layer;
forming a spacer layer over a side surface and an upper surface of the gate stack to leave an exposed portion of the crystalline silicon germanium layer;
removing a portion of the crystalline silicon germanium layer to leave an exposed portion of the active region; and
forming an elevated source and drain (source/drain) region over the exposed portion of the active region,
wherein the elevated source/drain region includes:
a top portion having a side surface in contact with the spacer layer, the top portion having a first lateral width; and
a bottom portion having a side surface in contact with the crystalline silicon germanium layer, the bottom portion having a second lateral width,
wherein the second lateral width is greater than the first lateral width.
